(19) United States
(12) Patent Application Publication
(10) Pub. No.: US 2008/0290430 A1
(43) Pub. Date: Nov. 27, 2008

(54) Stress-Isolated MEMS Device and Method Therefor

(75) Inventors: Dave S. Mahadevan, Mesa, AZ (US); Daniel N. Koury, JR., Mesa, AZ (US)

Correspondence Address: MESCHKOW & GRESHAM, P.L.C., 5727 NORTH SEVENTH STREET, SUITE 409, PHOENIX, AZ, 85014, US

(73) Assignee: FREESCALE SEMICONDUCTOR, INC., Austin, TX (US)

(21) Appl. No.: 11/753,851

(22) Filed: May 25, 2007

(51) Int. Cl. H01L 29/84; H01L 21/52

(52) U.S. Cl. 257/418; 257/415; 438/50; 257/E29.324; 257/E21.511; 257/E23.181; 257/E23.002; 257/E21.5; 257/E23.031

(57) ABSTRACT

A stress-isolated MEMS device (14) includes a platform (26) suspended over a substrate wafer (24). In one embodiment, the platform (26) is suspended by springs (38), but other suspension techniques may also be used. A transducer (28) is formed over the platform (26). The transducer (28) includes immovable portions (50) and movable portions (52). The transducer (28) and platform (26) are sealed within a cavity (62) formed within a cap support (30) between a cap wafer (32) and the substrate wafer (24). A leadframe (22) is affixed to the substrate wafer (24). The cap wafer (32) and other portions of the device (14) become embedded in a package material (20) so that a substantially solid boundary forms between the cap wafer (32) and the package material (20).

### TECHNICAL FIELD OF THE INVENTION

The present invention relates generally to micro-electrical-mechanical systems (MEMS). More specifically, the present invention relates to a MEMS device having a transducer which is stress-isolated from a leadframe and package material.

### BACKGROUND OF THE INVENTION

MEMS devices can be sensitive to temperature-induced stresses. In general, MEMS devices are fabricated using a variety of different materials. Each material has its own peculiar coefficient of thermal expansion. As a MEMS device experiences a temperature change, the different materials expand or contract different amounts per degree of temperature change.

In a conventional MEMS device, a silicon-based substrate wafer layer is attached over a leadframe layer, typically made from copper, Kovar, alloy 42, or similar metallic materials. A sacrificial layer, typically an oxide or silicon, attaches over the substrate layer, and a structural layer, typically another silicon-based layer, attaches over the sacrificial layer. The upper structural layer serves as an active transducer layer and is configured to have movable portions that have been released from adjacent immovable portions of the upper silicon-based layer and also from the underlying substrate layer. The immovable portions remain anchored to the underlying substrate layer. These and other layers are typically enclosed in a package made from yet another material that typically has yet another coefficient of thermal expansion.

As the various materials expand and contract at different rates in the presence of temperature changes, the active transducer layer may experience stretching, bending, warping, and other deformations due to the different dimensional changes of the different materials. As a result, the mechanical cooperation and responses of the movable and immovable portions of the MEMS device and the resulting electrical characteristics may change more than is desired. Accordingly, many conventional MEMS devices incorporate some form of stress isolation so that the mechanical and electrical characteristics are less sensitive to temperature changes.

Unfortunately, conventional forms of stress isolation have resulted in undesirably large and expensive packages or MEMS devices that are excessively difficult to produce, have low yield, and are too expensive. The use of undesirably large and/or expensive devices has prevented the incorporation of MEMS devices in some apparatuses, and/or prevented the incorporation of as many MEMS devices as may be desired in other apparatuses.

One conventional stress isolation technique places a MEMS transducer in an expensive ceramic cavity package, which is then hermetically sealed to prevent moisture leakage. To be effective for the purposes of stress isolation, a significant amount of free space exists between the MEMS transducer and the interior walls of the cavity package. The incorporation of a significant amount of free space within the package is also undesirable because it causes the packages to be larger than desired.

Another conventional stress isolation technique resiliently attaches a substrate die for the MEMS transducer to a leadframe using a flexible die attach adhesive and overcoats the MEMS transducer with a soft material, such as a silicon gel die coat, prior to embedding the MEMS transducer in an epoxy package material. This technique also results in an undesirably large and expensive MEMS device. A large amount of silicon gel is deposited over the MEMS transducer to ensure adequate coverage to stress isolate the MEMS transducer from the package. This large amount of silicon gel causes the resulting package to be larger than desired and also increases costs due the silicon gel material involved and the process step added by the application of this gel in a well controlled and consistent manner. And, the resilient attachment of the substrate die to the leadframe increases process costs due to the unusual resilient attachment technique and the increased care needed to attach wire bonds.

Another conventional stress isolation technique undercuts a portion of a substrate on which a MEMS transducer has been formed so that the MEMS transducer is situated on a substrate cantilevered paddle. But the undercutting of a substrate after formation of a MEMS transducer is a highly undesirable process that is difficult to implement in a controlled manner in practice and adds unwanted process steps. Consequently, yields are low and/or expenses are excessive.

Accordingly, it is desirable to provide a MEMS device and method that stress isolates a MEMS transducer from its package while permitting the overall package size and/or cost to be as small as reasonably practical.

### BRIEF DESCRIPTION OF THE DRAWINGS

A more complete understanding of the present invention may be derived by referring to the detailed description and claims when considered in connection with the Figures, wherein like reference numbers refer to similar items throughout the Figures, and:

FIG. 1 shows an apparatus about which inertial effects are measured and which uses a MEMS device to sense the inertial effects;

FIG. 2 shows a side view of a representative MEMS device configured in accordance with a first embodiment of the present invention;

FIG. 3 shows a top view of portions of the MEMS device depicted in FIG. 2;

FIG. 4 shows a side view of portions of a second embodiment of the present invention;

FIG. 5 shows a side view of portions of a third embodiment of the present invention; and

FIG. 6 shows a side view of portions of a fourth embodiment of the present invention.

### DETAILED DESCRIPTION

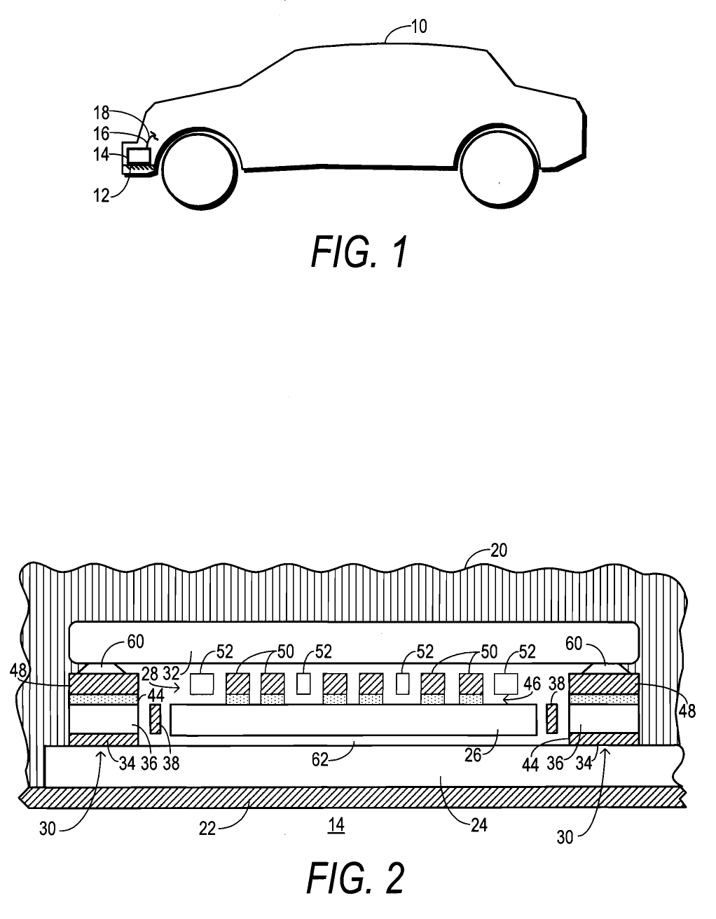

FIG. 1 shows an apparatus 10 about which physical effects are transduced with electrical signals. FIG. 1 depicts apparatus 10 in the form of a vehicle, where physical effects may be measured to control the deployment of airbags, to assist in stability management, and the like. But other types of apparatuses may also serve as apparatus 10. For example, a camera may measure physical effects for image stabilization purposes; hard disk drives and laptops may measure physical effects for free-fall detection; game controllers, cell phones, and/or personal digital assistants (PDA's) may measure physical effects for gesture recognition and/or tilt sensing; and, many other types of apparatuses may benefit from transducing physical effects with electrical signals.

Apparatus 10 includes a base 12 positioned in both location and orientation to experience and/or benefit from the physical effects of interest. In the vehicle example depicted in FIG. 1, base 12 may be located well forward in the vehicle's crush zone for purposes of transducing a rapid deceleration into electrical signals which lead to the deployment of an airbag, but base 12 may also be located in the passenger compartment or elsewhere.

Apparatus 10 also includes a micro-electrical-mechanical systems (MEMS) device 14 (not shown to scale) mounted on base 12. Device 14 generates and/or responds to electrical signals 16 provided over a wired, optical, or RF link 18 in a manner well understood to those of skill in the art. Device 14 is configured as a sensor, and more particularly as an accelerometer in the application specifically depicted in FIG. 1. But MEMS device 14 need not be configured only as an accelerometer or even a sensor. Rather, MEMS device 14 may also be configured to function in a wide variety of transducer applications. Desirably, MEMS device 14 is provided in as small and inexpensive a package as is reasonably practical. The use of small and inexpensive packages allows more MEMS devices 14 to be included in a given volume of space and allows MEMS devices 14 to be used in apparatuses 10 where they have heretofore been impractical.

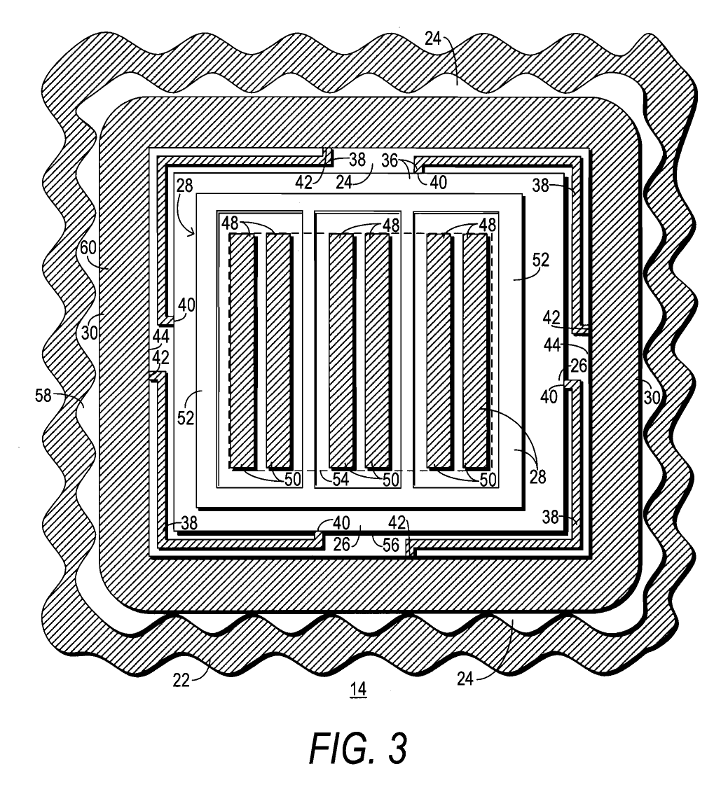

FIG. 2 shows a side view of a representative MEMS device 14 configured in accordance with a first embodiment of the present invention. FIG. 3 shows a top view of portions of the MEMS device 14 depicted in FIG. 2. Those skilled in the art will appreciate that for purposes of clarity in illustrating the various features discussed below, FIGS. 2-3 and the subsequent Figures do not depict the features to scale or include all details. The following discussion refers to FIGS. 2 and 3.

In general, MEMS device 14 can include a package material 20, leadframe 22, substrate wafer 24, platform 26, transducer 28, cap support 30, and cap wafer 32. FIG. 3 omits package material 20 and cap wafer 32 for the sake of clarity. MEMS device 14 may also include many other components well known to those of skill in the art but also omitted from the Figures for the sake of clarity. For example, an application-specific integrated circuit (ASIC) is commonly used to interface directly with a MEMS transducer, such as transducer 28, and such an ASIC is often enclosed with the MEMS transducer in a common package. Wire bonds and/or other semiconductor conductive track routing techniques may be used to interconnect the two. Although not specifically depicted in the Figures, such an ASIC, such wire bonds, and supporting metallization layers may be included within package material 20. Such an ASIC may be located beside, beneath, or above cap support 30 or may be fabricated on the substrate 24 or cap wafer 32 for transducer 28.

Those skilled in the art will appreciate that relational orientation terms used herein, such as over, overlying, under, underlying, underneath, beside, beneath, above, bottom, top, upward, height, horizontal, downward, and the like, refer to the orientations depicted in the FIGS. 2-6 and not to the direction of gravity in any particular application.

In the preferred embodiments, substrate wafer 24 is desirably a conventional silicon based, often monocrystalline silicon, wafer used in semiconductor processing applications. But the use of such a material is not a requirement. Substrate wafer 24 serves as a supporting material upon which the remainder of MEMS device 14 is fabricated.

Starting with substrate wafer 24, hereinafter referred to as substrate 24, a sacrificial layer 34 is applied to overlie substrate 24. Sacrificial layers, such as layer 34, may be made of an oxide but in any event is desirably formed of a different material than substrate 24. The use of an oxide for sacrificial layer 34 is desirable in some applications because it insulates substrate 24 from the layer to be applied over sacrificial layer 34, thereby allowing different potentials to be applied to these layers without additional processing tasks. Sacrificial layer 34 is applied using conventional techniques to a depth that is useful for the particular application. The use of different materials for substrate 24 and sacrificial layer 34 is desirable because it allows a subsequent release-etching task to occur in a reliable and controlled manner. Sacrificial layer 34 may be patterned and etched where electrical contact, mechanical support, or etch selectivity is desired (not shown).

A structural layer 36 is then formed over sacrificial layer 34. Structural layers, such as layer 36, may be formed from polycrystalline silicon to a depth that is useful for a particular application using conventional techniques, but this is not a requirement. It is however useful in the fabrication of MEMS device 14 that sacrificial and structural layers be formed of different materials, or alternately of differently doped semiconductor material, so that a first etchant may remove desired patterns in the sacrificial layer without significantly removing the structural layer, and so that a second etchant may remove desired patterns in the structural layer without significantly removing the sacrificial layer.

In one embodiment, patterning and etching operations are then performed to form platform 26. The formation of platform 26 entails the removal of structural layer 36 from around the perimeter of platform 26. The etching operation of platform 26 may also form a multiplicity of small holes (not shown) in structural layer 36 to assist in the removal of sacrificial layer 34 from underneath platform 26 later in the process, preferably after the formation of transducer 28 described below. The use of a material for sacrificial layer 34 that differs from the materials of substrate 24 and from platform 26 allows this later release-etching task to occur in a reliable and controlled manner.

But structural layer 36 is desirably not completely removed from around the perimeter of platform 26. Rather, in the embodiment depicted in FIGS. 2-3 springs 38 are formed in structural layer 36 and released from substrate 24 by removing sacrificial layer 34 from underneath springs 38. Springs 38 remain attached to platform 26 at points 40 by refraining from removing structural layer 36 at points 40. Likewise, at selected points 42 springs 38 attach to a perimeter wall 44 which surrounds but is spaced apart from platform 26. Springs 38 reside in the gap between perimeter wall 44 and platform 26. Those skilled in the art will appreciate that springs 38 are intended to represent any structure or structures that function as springs and that springs 38 may take on a wide variety of shapes other than the simplistic ones depicted for convenience in FIG. 3.

Perimeter wall 44 remains anchored to substrate 24, and is shown as being a lower portion of cap support 30 in FIGS. 2-3. But in alternate embodiments, perimeter wall 44 may be separated inwardly from cap support 30 and independently anchored to substrate 24. Perimeter wall 44 continuously surrounds platform 26 in the embodiment depicted in FIGS. 2-3, but this is not a requirement.

In the embodiment depicted in FIGS. 2-3, it is springs 38 that movably suspend platform 26 over substrate 24. Movement in the geometry of substrate 24, such as bending, warping, stretching, or other dimensional instabilities, that may result from temperature-induced stress is not transmitted to platform 26 but is absorbed by springs 38. In other words, by movably suspending platform 26 over substrate 24, platform 26 becomes isolated from the stresses that affect substrate 24 and the resulting changes in the geometry of substrate 24 that result from such stresses.

After the formation of platform 26, transducer 28 is formed over platform 26. A sacrificial layer 46 is applied over platform 26, and then a structural layer 48 is applied over sacrificial layer 46. The material from which sacrificial layer 46 is formed is desirably chosen to be the same as sacrificial layer 34 so that both may be removed in a single process. Patterning and etching operations are performed on sacrificial layer 46 to provide stationary “anchor” locations where structural layer 48 will attach to platform 26. Desirably, structural layer 48 and structural layer 36 are formed from substantially identical materials so that their coefficients of thermal expansion will be substantially identical, so that no substantial thermal-induced stress will result from the interface between transducer 28 and platform 26, and so that only a single etch-release task may be performed to simultaneously release platform 26 from substrate 24 and portions of structural layer 48 from platform 26.

Patterning and etching operations are next performed to produce immovable or stationary portions 50 of transducer 28 and movable portions 52 of transducer 28. Immovable and movable portions 50 and 52 are separated from one another by etching away portions of layer 48 that reside between portions 50 and 52. Movable portions 52 are made movable by etching away much, or all, of sacrificial layer 46 from underneath movable portions 52 of structural layer 48 and from the gaps between immovable and movable portions 50 and 52. As discussed above, in one embodiment a single etch-release task may be performed to release movable portions 52 from platform 26 and to remove platform 26 from substrate 24. Using only a single etch-release task is desirable because it lowers costs and improves yield.

Those skilled in the art will appreciate that the terms “immovable” and “movable” are relative terms as used herein and that they are relative to each other. Thus, immovable portions 50 are considered stationary or immovable relative to the underlying layer on which they are formed, in this case platform 26, and relative to movable portions 52. Furthermore, immovable features of MEMS device 14, including portions 50, are considered immovable relative to platform 26 because they move much less than movable portions 52 within the range over which MEMS device 14 is designed to operate normally. Clearly, immovable portions of MEMS device 14, including immovable portions 50 may, in fact, move when platform 26 moves relative to substrate 24 and when apparatus 10 moves. In contrast, movable portions 52 are considered movable relative to the underlying layer on which they are formed, in this case platform 26, and relative to immovable portions 50.

In the preferred embodiments, movable portions 52 of transducer 28 move relative to platform 26, and platform 26 moves relative to substrate 24. It is desirable that the physical effects to be transduced with electrical signals by MEMS device 14 be a function of the movement of movable portions 52 of transducer 28 and far more than of platform 26. Accordingly, the resonant frequency of movable portions 52 of transducer 28 is desirably designed to differ from, and desirably be lower than, the resonant frequency collectively exhibited by platform 26 and transducer 28.

Different resonant frequencies may be achieved, for example, by configuring transducer 28 to operate in a desired range of physical effect to be transduced with electrical signals 16, which results in a resonant frequency for movable portions 52 of transducer 28. Springs 38 which suspend platform 26 above substrate 24 may then be designed to achieve a significantly higher resonant frequency for platform 26 in combination with transducer 28 so that the two movable components of MEMS device 14 do not interfere with one another. Those skilled in the art will appreciate that the resonant frequency collectively exhibited by platform 26 and transducer 28 may be controlled by specifying the width and length of springs 38 and by specifying the placement of points 40 and 42 for springs 38.

In the preferred embodiments, anchors of immovable portions 50 of transducer 28 overlie a footprint area 54, shown as a dotted-line box in FIG. 3. Platform 26 is larger, or at least equal in area to, footprint area 54. Thus, platform 26 overlies a footprint area 56 which is greater than or equal to footprint area 54. And, substrate 24 overlies a footprint area 58 which is greater than or equal to footprint area 56. FIG. 3 shows only a portion of the footprint area 58, and that portion is greater than footprint area 56. This arrangement allows platform 26 to be suspended over substrate 24 and the anchors of immovable portions 50 of transducer 28 to be positioned over and anchored to platform 26.

FIG. 3 depicts a simplistic form of an interdigitated capacitance structure that might, preferably in a more complex form understood by those of skill in the art, be used in a MEMS device configured to serve as a accelerometer. Other features, such as springs, conductance paths, additional capacitance structures, and other structures that are conventional in MEMS transducers may also be included in transducer 28, but are omitted from FIGS. 2-3 for clarity. In one embodiment, movable and immovable portions 52 and 50 are not required to form a capacitance structure. Those skilled in the art will appreciate that any of a wide variety of MEMS structures known to those skilled in the art may be formed over platform 26.

For the accelerometer example, the physical effect of acceleration (or deceleration) is sensed because the physical effect causes a small movement in movable portion 52 relative to immovable portion 50, and that small movement alters the differential capacitance exhibited by transducer 28. By electronically monitoring the differential capacitance, the physical effect is transduced with electrical signals in a manner well understood to those skilled in the art.

Cap support 30 is a ring-shaped columnar structure that extends upward above substrate 24 to a height that supports cap wafer 32 above transducer 28. In the embodiment depicted in FIG. 2, cap support 30 includes portions of layers 34, 36, 46, and 48, in addition to, for example, a screen-applied glass frit layer 60 over structural layer 48. However, in another embodiment, layers 34, 36, 46, and 48 are not required to be a part of cap support 30. Desirably, cap support 30 horizontally surrounds platform 26 and transducer 28.

Cap wafer 32 may be a conventional silicon-based wafer similar to substrate wafer 24. Cap wafer 32 may be bonded to substrate wafer 24 by glass frit layer 60 by applying pressure to hermetically seal a cavity 62 in which platform 26 and transducer 28 are enclosed. Cavity 62 is formed inside cap support 30 between substrate 24 and cap wafer 32. Desirably, a sufficient air gap resides above transducer 28 so that no warping, bending, stretching, or other deformation of cap wafer 32 will cause interference with the operation of transducer 28. Of course, those skilled in the art will appreciate that the air gaps within cavity 62 need not be filled with air but may desirably be occupied by a more inert gas, such as nitrogen, or may be at a vacuum.

The structure which includes substrate 24, cap support 30, cap wafer 32, platform 26 and transducer 28 is immovably attached to leadframe 22 using a suitable adhesive, which may be a room temperature vulcanizing (RTV) or epoxy material (not shown) applied between the bottom of substrate 24 and a mounting section of leadframe 22. The adhesive may be applied in any convenient manner that causes substrate 24 to be rigidly affixed to leadframe 22. For example, the adhesive may be distributed evenly over the entire surface area between substrate 24 and a mounting surface of leadframe 22. This technique lowers costs by avoiding special leadframe attachment processes that are more costly in and of themselves and that make wire bonding operations more difficult.

Package material 20 is preferably applied in accordance with a conventional low cost molding process. A conventional polymeric package material 20, such as epoxy or any other suitable material, may be used. In accordance with the preferred embodiments, package material 20 comes into contact with cap wafer 32, as well as cap support 30, substrate 24, and leadframe 22. Thus, at least portions of cap wafer 32 are embedded within package material 20. Likewise, at least portions of substrate wafer 24 and leadframe 22 are embedded within package material 20. After setting, this forms a solid boundary with cap wafer 32. In other words, no significant amount of gas, liquid, or gel is present between cap wafer 32 and package material 20, and any materials that may be used between package material 20 and cap wafer 32 are desirably held to being thin layers or coatings which do little to buffer the formation of temperature-induced stresses at this boundary. But such stresses are substantially isolated from transducer 28 and platform 26 in MEMS device 14 due to the suspension of platform 26 above substrate 24. Since no stress-buffering materials are imposed between cap wafer 32 and package material 20, the overall package size defined by the exterior surface of package material 20 (not shown) may be smaller than packages that include such stress-buffering materials.

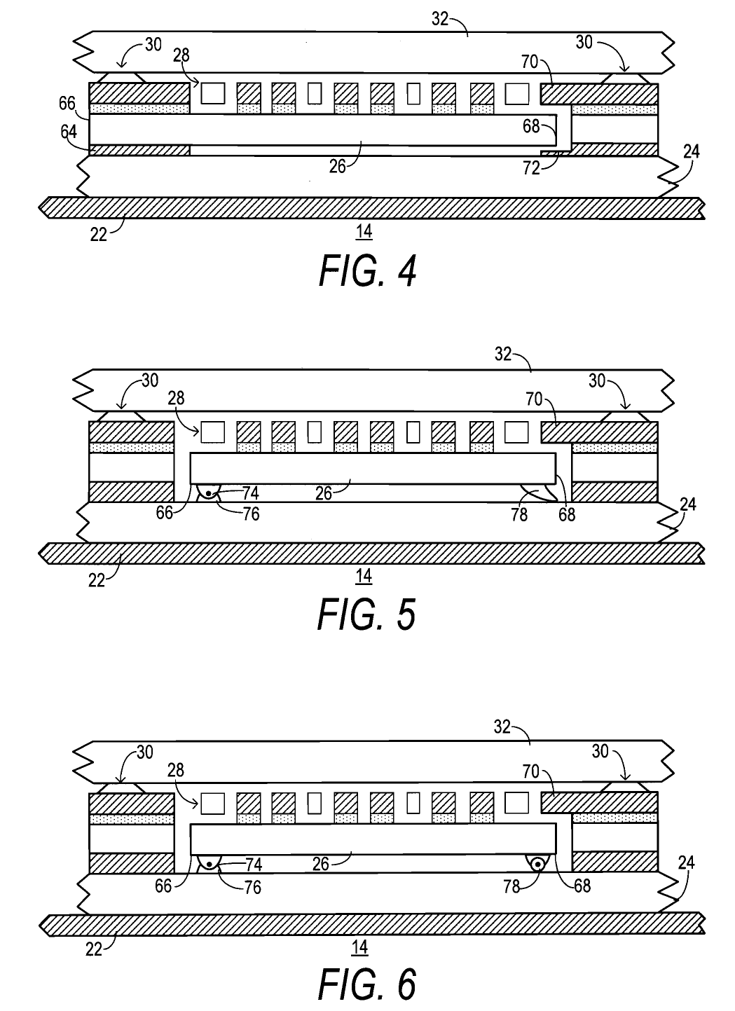

FIG. 4 shows a side view of portions of a second embodiment of MEMS device 14. This second embodiment is much like the embodiment discussed above in connection with FIGS. 2-3. But in this second embodiment, platform 26 is cantilevered over substrate wafer 24 rather than being suspended by springs. Transducer 28 is formed over platform 26 much like discussed above, cap wafer 32 bonds to cap support 30 much like discussed above, and package material 20 (not shown in FIG. 4) and leadframe 22 are provided much like discussed above.

But FIG. 4 depicts a platform support 64 integrally formed with cap support 30. At an anchor edge 66 of platform 26, platform 26 attaches to support 64 and through support 64 becomes immovably coupled to substrate 24. Nothing requires platform support 64 to be integrally formed with cap support 30 as depicted in FIG. 4. Instead, a structure may be formed separated from and inside of cap support 30 to serve as platform support 64.

Preferably, platform support 64 does not extend the entire length of anchor edge 66, along the dimension perpendicular to the two dimensions depicted in FIG. 4. Rather, a small number, for example two, of platform supports 64 are desirably formed, with one of platform supports 64 being located at or near each of the corners for anchor edge 66. Moreover, platform supports 64 are desirably configured to exhibit some flexibility, such as may be accomplished by configuring supports 64 in the form of stiff springs. Thus, any dimensional instability in substrate 24 along this dimension perpendicular to the two dimensions depicted in FIG. 4. will not be transmitted to platform 26 but will be absorbed by supports 64.

A free edge 68 of platform 26 opposes anchor edge 66. A top stop 70 may reside over free edge 68, but spaced apart from the top surface of platform 26. Top stop 70 prevents platform 26 from excess movement. A bottom stop 72 may reside under free edge 68, but is spaced apart from the bottom side of platform 26. Bottom stop 72 prevents excessive movement of free edge 68 in a downward direction. In an alternate embodiment (not shown) bottom stop 72 is fixedly formed underneath platform 26 proximate free edge 68 and moves commonly with free edge 68 of platform 26.

Accordingly, any warping, bending, stretching, distorting, or other dimensional instability that may affect substrate 24 due to temperature changes and to its attachment to leadframe 22 and package material 20 is substantially isolated from platform 26 and transducer 28 formed on platform 26 because the cantilevering of platform 26 over substrate 24 accommodates relative movement between substrate 24 and platform 26.

FIG. 5 shows a side view of portions of a third embodiment of MEMS device 14. This third embodiment is much like the embodiments discussed above in connection with FIGS. 2-4. But in this third embodiment, platform 26 is suspended over substrate wafer 24 by hinge and friction-contact supports rather than being suspended by springs or cantilevering. Transducer 28 is formed over platform 26 much like discussed above, cap wafer 32 bonds to cap support 30 much like discussed above, and package material 20 (not shown in FIG. 5) and leadframe 22 are provided much like discussed above.

At anchor edge 66 of platform 26 a hinge 74 couples platform 26 to substrate 24. In particular, a platform anchor 76 extends above substrate 24 underneath platform 26. Platform anchor 76 is anchored to substrate 24. Underneath platform 26 at or near anchor edge 66, platform 26 is hinged to platform anchor 76. Those skilled in the art will appreciate that hinge 74 is broadly defined herein to include any structure that functions as a hinge. In other words, hinge 74 restrains relative lateral motion of platform 26 and substrate 24 in at least two dimensions while permitting rotation.

As discussed above in connection with the FIG. 4 embodiment, hinge 74 desirably does not extend the entire length of anchor edge 66, along the dimension perpendicular to the two dimensions depicted in FIG. 5. Rather, one or two separate hinges 74 are desirably formed, with a single hinge being near the center of anchor edge 66, or two hinges 74 being located at or near each of the corners for anchor edge 66.

A movable support 78 in the form of a sliding contact is positioned underneath platform 26 at or near free edge 68. In one embodiment, one or more movable supports 78 are positioned along free edge 68 along the dimension perpendicular to the two dimensions depicted in FIG. 5. In response to any warping, bending, stretching, distorting, or other dimensional instability that may affect substrate 24, free edge 68 of platform 26 is free to move relative to substrate 24 as needed so that platform 26 remains substantially free from such stresses.

FIG. 6 shows a side view of portions of a fourth embodiment of MEMS device 14. This fourth embodiment is much like the embodiments discussed above in connection with FIGS. 2-5. But in this fourth embodiment, platform 26 is suspended over substrate wafer 24 by hinge and roller supports rather than being suspended by springs, cantilevering, or sliding contacts. Transducer 28 is formed over platform 26 much like discussed above, cap wafer 32 bonds to cap support 30 much like discussed above, package material 20 (not shown in FIG. 6) and leadframe 22 are provided much like discussed above, and hinge 74 is provided much like discussed above.

The FIG. 6 embodiment differs from the FIG. 5 embodiment in that a movable support 78 in the form of a roller is positioned under free edge 68 of platform 26 to support platform 26 over substrate 24 while permitting relative motion therebetween. A roller is broadly defined herein to mean any structure that functions as a roller. In other words, the movable support 78 accommodates lateral movement in at least one dimension while restraining vertical motion.

A stress-isolated MEMS device and method therefor are provided by at least one embodiment of the present invention. At least one embodiment of the present invention encourages the formation of a small package because stress-isolation is accomplished through the use of silicon-based structures rather than through the use of soft buffering materials at boundaries with packaging material and/or a leadframe. And at least one embodiment of the present invention provides a low cost package because inexpensive package materials may be used in combination with conventional assembly steps, because the use of a soft buffering material, such as a silicon gel, can be avoided, and because the device may be implemented using conventional and reliable processing techniques.

Although the preferred embodiments of the invention have been illustrated and described in detail, it will be readily apparent to those skilled in the art that various modifications may be made therein without departing from the spirit of the invention or from the scope of the appended claims.

What is claimed is:

1. A MEMS device comprising:
a substrate wafer;
a sacrificial layer overlying a first portion of said substrate wafer, said sacrificial layer not overlying a second portion of said substrate wafer, and said sacrificial layer being formed of a different material than said substrate wafer;
a platform movably suspended over said second portion of said substrate wafer; and
a transducer having an immovable portion positioned over and rigidly affixed to said platform and having a movable portion movably suspended over said platform.

2. A MEMS device as claimed in claim 1 additionally comprising a cap support surrounding said transducer and said platform.

3. A MEMS device as claimed in claim 1 additionally comprising a cap wafer overlying said transducer and bonded to said substrate wafer so that said transducer and said platform are enclosed together within a cavity formed between said substrate wafer and said cap wafer.

4. A MEMS device as claimed in claim 3 wherein said cap wafer is embedded within a package material so as to provide a substantially solid boundary between said cap wafer and said package material.

5. A MEMS device as claimed in claim 3 wherein said transducer and said platform are hermetically sealed together within a cavity formed inside said cap support and between said substrate wafer and said cap wafer.

6. A MEMS device as claimed in claim 1 wherein said immovable portion of said transducer overlies a first footprint area, said platform overlies a second footprint area greater than or equal to said first footprint area, and said substrate wafer overlies a third footprint area greater than said second footprint area.

7. A MEMS device as claimed in claim 1 additionally comprising a leadframe rigidly affixed to said substrate wafer.

8. A MEMS device as claimed in claim 1 wherein:
said MEMS device additionally comprises a perimeter wall anchored to said substrate wafer and surrounding said platform; and
said platform is suspended on springs within said perimeter wall.

9. A MEMS device as claimed in claim 1 wherein:
said MEMS device additionally comprises a platform anchor rigidly coupled to said substrate wafer; and
said platform has an edge at which said platform is hinged to said platform anchor and from which said platform extends over said substrate wafer.

10. A MEMS device as claimed in claim 9 additionally comprising a movable support affixed to said platform, positioned between said substrate wafer and said platform, and configured to accommodate movement of said substrate wafer relative to said platform.

11. A MEMS device as claimed in claim 1 wherein said platform and said movable portion of said transducer are formed of substantially identical materials.

12. A method of isolating a MEMS device from temperature-induced stress, said method comprising:
applying a sacrificial layer overlying a substrate wafer, said sacrificial layer being formed from a material different than said substrate wafer;
suspending a platform over said substrate wafer by removing a portion of said sacrificial layer so as to allow movement of said platform relative to said substrate wafer; and
forming a transducer on said platform, said transducer having an immovable portion fixedly attached over said platform and a moveable portion suspended over said platform so as to allow movement of said moveable portion relative to said immovable portion and said platform.

13. A method as claimed in claim 12 wherein said suspending activity and said forming activity form said platform and said movable portion of said transducer from substantially identical materials.

14. A method as claimed in claim 12 additionally comprising:
bonding a cap wafer to said substrate wafer so that said transducer and said platform are enclosed together within a cavity formed between said substrate wafer and said cap wafer.

15. A method as claimed in claim 14 additionally comprising embedding said cap wafer within a package material so as to provide a substantially solid boundary between said cap wafer and said package material.

16. A method as claimed in claim 12 wherein:
said forming activity configures said movable portion of said transducer to exhibit a first resonant frequency; and
said suspending activity configures said platform and transducer to collectively exhibit a second resonant frequency different from said first resonant frequency.

17. An apparatus about which physical effects are transduced with electrical signals comprising:
a base positioned to experience said physical effects;
a MEMS sensor device mounted on said base, said MEMS sensor device comprising:
a leadframe;
a substrate affixed to said leadframe;
a platform movably suspended over said substrate; and
a transducer formed over said platform, said transducer having an immovable portion fixed over said platform and a movable portion movably coupled to said platform and configured to respond to one of said physical effects and said electrical signals.

18. An apparatus as claimed in claim 17 additionally comprising a sacrificial layer overlying a first portion of said substrate wafer and underlying a layer from which said platform is formed, said sacrificial layer not overlying a second portion of said substrate wafer, said sacrificial layer not underlying said platform, and said sacrificial layer being formed of a different material than said substrate wafer.

19. An apparatus as claimed in claim 18 wherein said platform and said movable portion of said transducer are formed of substantially identical materials.

20. An apparatus as claimed in claim 19 additionally comprising:
a cap wafer overlying said MEMS device and bonded to said substrate so that said MEMS device and said platform are enclosed within a cavity formed between said substrate and said cap wafer; and
a package material within which said cap wafer is embedded to form a substantially solid boundary between said cap wafer and said package material.
